(19) United States
(12) Patent Application Publication
(10) Pub. No.: US 2025/0142880 A1
(43) Pub. Date: May 1, 2025

(54) FIELD EFFECT TRANSISTOR HAVING AN ELECTRODE TRENCH STRUCTURE

(71) Applicant: Infineon Technologies AG, Neubiberg (DE)

(72) Inventor: Andreas Hoffmann, München (DE)

(21) Appl. No.: 18/927,180

(22) Filed: Oct. 25, 2024

(30) Foreign Application Priority Data
Oct. 27, 2023 (DE) 102023129739.2

(51) Int. Cl. H01L 29/78; H01L 21/265; H01L 29/10; H01L 29/66

(52) U.S. Cl. CPC H10D 30/668; H01L 21/26513; H10D 30/0297; H10D 62/393

(57) ABSTRACT

A FET includes a semiconductor substrate having a mesa arranged between an electrode trench structure along a first lateral direction. A groove contact extends into the mesa from a top surface of the mesa. A bottom of the groove contact is located at a first vertical reference level. The mesa includes a source region, a body structure, and a drift region. A pn junction between the drift region and body structure has a minimum vertical distance to the mesa top surface at a second vertical reference level and a maximum vertical distance to the mesa top surface at a third vertical reference level. At a fourth vertical reference level between the second and first vertical reference levels, a doping concentration of the body structure increases by a factor of 5 to 100 along the first lateral direction from the electrode trench structure towards the mesa center. The first vertical distance is by a factor of 1.5 to 10 larger than a second vertical distance from the fourth to the second vertical reference level.

### TECHNICAL FIELD

The present disclosure is related to a semiconductor device, in particular to a field effect transistor, FET, comprising an electrode trench structure and a manufacturing method thereof.

### BACKGROUND

Technology development of new generations of semiconductor devices, e.g. field effect transistors (FETs), aims at improving electric device characteristics and reducing costs by shrinking device geometries. Although costs may be reduced by shrinking device geometries, a variety of tradeoffs and challenges have to be met when increasing device functionalities per unit area. For example, a trade-off between area-specific on-state resistance, RₒₙxA and reliability requirements influenced by, for example, avalanche breakdown behavior requires design optimization.

Thus, there is a need for an improved field effect transistor.

### SUMMARY

An example of the present disclosure relates to a field effect transistor, FET. The FET includes a semiconductor substrate having a mesa arranged between an electrode trench structure along a first lateral direction. The FET further includes a groove contact extending into the mesa from a top surface of the mesa. A bottom of the groove contact is located at a first vertical reference level. The mesa includes a source region of a first conductivity type, a body structure of a second conductivity type and a drift region of the first conductivity type. The drift region forms a pn junction with the body structure. The pn junction has a minimum vertical distance to the top surface of the mesa at a second vertical reference level and a maximum vertical distance to the top surface of the mesa at a third vertical reference level. At a fourth vertical reference level, a doping concentration of the body structure increases by a factor of 5 to 100 along the first lateral direction from the electrode trench structure towards a center of the mesa. The fourth vertical reference level is located between the second vertical reference level and the first vertical reference level at a first vertical distance to the first reference level. The first vertical distance is by a factor of 1.5 to 10 larger than a second vertical distance from the fourth vertical reference level to the second vertical reference level.

Another example of the present disclosure relates to a method of manufacturing a field effect transistor, FET. The method includes forming a mesa arranged in a semiconductor substrate between an electrode trench structure along a first lateral direction. The method further includes forming a groove contact extending into the mesa from a top surface of the mesa. A bottom of the groove contact is located a first vertical reference level. The method further includes forming a source region of a first conductivity type in the mesa. The method further includes forming a body structure of a second conductivity type in the mesa. The method further includes forming a drift region of the first conductivity type in the mesa. The drift region forms a pn junction with the body structure. The pn junction has a minimum vertical distance to the top surface of the mesa at a second vertical reference level and a maximum vertical distance to the top surface of the mesa at a third vertical reference level. At a fourth vertical reference level, a doping concentration of the body structure increases by a factor of 5 to 100 along the first lateral direction from the electrode trench structure towards a center of the mesa. The fourth vertical reference level is located between the second vertical reference level and the first vertical reference level at a first vertical distance to the first reference level. The first vertical distance is by a factor of 1.5 to 10 larger than a second vertical distance from the fourth vertical reference level to the second vertical reference level.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of FETs and together with the description serve to explain principles of the examples. Further examples are described in the following detailed description and the claims.

FIG. 1A is a schematic cross-sectional view for illustrating a configuration example of a FET including a groove contact and a body structure.

FIG. 1B is a schematic graph for illustrating an exemplary doping concentration profile of the body structure along a lateral direction at a fourth vertical reference level.

FIG. 2 is a schematic graph for illustrating an exemplary doping concentration profile of the body structure along a vertical direction at a center of the mesa.

FIG. 3 is a schematic cross-sectional view for illustrating a configuration example of a FET including an electrode trench structure having a gate electrode and a field electrode.

FIGS. 4A to 4D are schematic cross-sectional views for illustrating process features of manufacturing a FET including a groove contact and a body structure.

### DETAILED DESCRIPTION

In the following detailed description, reference is made to the accompanying drawings, which form a part hereof and in which are shown by way of illustrations specific examples of FETs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions may include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a field effect transistor, FET. The FET includes a semiconductor substrate having a mesa arranged between an electrode trench structure along a first lateral direction. The FET further includes a groove contact extending into the mesa from a top surface of the mesa. A bottom of the groove contact is located at a first vertical reference level. The mesa includes a source region of a first conductivity type, a body structure of a second conductivity type and a drift region of the first conductivity type. The drift region forms a pn junction with the body structure. The pn junction has a minimum vertical distance to the top surface of the mesa at a second vertical reference level and a maximum vertical distance to the top surface of the mesa at a third vertical reference level. At a fourth vertical reference level, a doping concentration of the body structure may increase by a factor of 5 to 100 along the first lateral direction from the electrode trench structure towards a center of the mesa. The fourth vertical reference level is located between the second vertical reference level and the first vertical reference level at a first vertical distance to the first reference level. The first vertical distance may be by a factor of 1.5 to 10 larger than a second vertical distance from the fourth vertical reference level to the second vertical reference level.

The first conductivity type may be an n-type and the second conductivity type may be a p-type. In this case, the FET is an n-channel FET, for example. The first conductivity type may also be a p-type and the second conductivity type may be an n-type. In this case, the FET is a p-channel FET, for example.

For example, the FET may be a lateral FET. In a lateral FET, a load current flow direction is a lateral direction, and the source region and the drain region are spaced from each other along the lateral direction. For example, the lateral FET may be a lateral trench FET such as a lateral trench metal oxide semiconductor field effect transistor, lateral trench MOSFET. The FET may also be a vertical FET. In a vertical FET, a load current flow direction is a vertical direction, and the source region and the drain region are spaced from each other along the vertical direction. For example, the source region may be electrically connected to a source electrode over a first surface of the semiconductor substrate and the drain region may be electrically coupled to a drain electrode over a second surface of the semiconductor substrate, wherein the second surface is opposite to the first surface.

For example, the FET may be part of an integrated circuit, or may be a discrete semiconductor device or a semiconductor module. For example, the FET may be implemented monolithically using a mixed technology. Such mixed technologies can be used, for example, to form analog circuit blocks in a chip by the bipolar devices included in this technology for providing interfaces to digital systems, and to form digital circuit blocks by the complementary metal-oxide-semiconductor (CMOS) devices included in this technology for providing signal processing, and to form low-, medium- or high-voltage or power blocks by field effect transistors included in this technology. Such mixed technologies are known, for example, as bipolar CMOS-DMOS, BCD technologies or smart power technologies, SPT, and are used in a variety of application areas in the field of e.g. lighting, motor control, automotive electronics, power management for mobile devices, audio amplifiers, power supply, hard disks, printers. The FET may be part of a BCD or Smart Power chip in one of the above application fields, for example.

The semiconductor substrate may be based on various semiconductor materials, for example silicon (Si), silicon-on-insulator (SOI), silicon-sapphire (SOS), silicon-germanium, germanium, gallium arsenide, silicon carbide, gallium nitride, or other compound semiconductor materials. The semiconductor substrate may be based on a semiconductor base substrate, for example a semiconductor wafer and may include one or more epitaxial layers deposited thereon and/or may be back-thinned.

For realizing a desired current carrying capacity, the FET may be designed by a plurality of transistor cells that are parallel-connected. The parallel-connected transistor cells may, for example, be transistor cells formed in the shape of a strip or a strip segment. Of course, the transistor cells can also have any other shape, e.g. circular, elliptical, polygonal such as hexagonal or octahedral. The transistor cells may be arranged in a transistor cell area of the semiconductor substrate. The transistor cell area may be an active area where the source region of the FET is electrically connected to a source electrode. In the active area, a load current may enter or exit the semiconductor substrate of the FET, e.g. via contact plugs on the first surface of the semiconductor substrate.

The semiconductor substrate may have a first surface that may be a front surface or a top surface of the semiconductor substrate. The first surface may be the surface where the mesa with the source region is located, for example. The second surface may be a back surface or a rear surface of the semiconductor substrate, for example. For vertical FETs, the second surface may be the surface where the drain is located. The semiconductor substrate may be attached to a lead frame via the second surface, for example. Over the first surface of the semiconductor substrate, bond pads may be arranged and bond wires may be bonded on the bond pads, for example.

The source region and the body structure may be electrically connected to a source electrode via the groove contact. The source electrode and the groove contact may be part of a wiring area over the first surface of the semiconductor substrate, for example. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The groove contact may provide an electric contact between an active area in the semiconductor substrate and the first wiring level, the first wiring level being the wiring level closest to the first surface of the semiconductor substrate. The groove contact may include one or more conductive materials as well as adhesion and/or diffusion barrier materials/liners. The source electrode may be formed by one or more elements of the wiring area. Likewise, the FET may further include a drain electrode. Also the drain electrode may be formed by one or more elements of the wiring area over the first surface for lateral FETs. For example, the source electrode and the drain electrode may include separate parts of a patterned first wiring level, e.g. a first metal layer. In some examples related to lateral FETs, the drain electrode may also be formed over the second surface of the semiconductor substrate. In this case, a drain region of the FET may be electrically connected to the drain electrode by a through contact or trench contact extending at least partly through the semiconductor substrate. In some examples related to vertical FETs, the drain electrode may be formed over the second surface of the semiconductor substrate.

The drift region may extend from the mesa into a portion of the semiconductor substrate below the electrode trench structure, for example. The blocking voltage of the FET may, inter alia, be adjusted along a vertical direction perpendicular to the first surface by adjusting parameters of the drift region, e.g. vertical extent and/or doping profile. The drift region may turn into a highly doped drain region or into a buried layer region along the vertical direction, for example. A doping concentration in the drift region may gradually or in steps increase or decrease with increasing distance to the first surface at least in portions of its vertical extension. According to other examples the impurity concentration in the drift region may be approximately uniform in vertical direction.

The second vertical reference level may be at or close to the electrode trench structure. The third vertical reference level may be in a central region or in the center of the mesa with respect to the first lateral direction. A difference between the second vertical reference level and the third vertical reference level corresponds to a vertical extent of the pn junction in the mesa.

The body structure of the configuration examples described herein is related to a pn junction between the body structure and the drift region that has a vertical extension between the second vertical reference level and the third vertical reference level. A bottom or lowest point of the pn junction is in the central region of the mesa. This allows for keeping an avalanche current, e.g. holes in case of an n-channel FET, away from the sensitive channel region at the sidewalls of the electrode trench structure. Thereby avalanche robustness and safe operation area may be improved.

For example, the body structure may include a superposition of doping concentration profiles of at least a body region, a body contact region, and a body strengthening region. The pn junction at the third vertical reference level may coincide with an intersection, along the vertical direction, between a doping concentration profile of the body strengthening region and a doping concentration profile of the drift region. The body strengthening region of the body structure may thus be that part of the body structure that determines the avalanche breakdown behavior with respect to location of the hole avalanche current path for n-channel devices. The body region of the body structure may be that part of the body structure that determines the channel behavior, e.g. threshold voltage. The body contact region of the body structure may be that part of the body structure that determines the ohmic contact behavior to the groove contact, for example. By forming the body structure by the superposition of doping concentration profiles of at least the body region, the body contact region, and the body strengthening region, functional behavior of the FET may be separately tuned with respect to threshold voltage, avalanche breakdown robustness and ohmic contact behavior. Moreover, forming the body strengthening region (and the body contact region) by ion implantation of dopants through a bottom of the groove for the groove contact, no separate mask process is required for optimizing the avalanche breakdown robustness.

For example, a maximum concentration of the doping concentration profile of the body contact region may be larger by a factor of 5 to 200, or by a factor of 8 to 150, than a maximum concentration of the doping concentration profile of the body strengthening region. For example, dopants of the body contact region may be implanted with a higher dose but lower energy than dopants of the body strengthening region.

For example, a maximum concentration of the doping concentration profile of the body strengthening region may be larger by a factor of 5 to 200, or by a factor of 8 to 150, than a maximum concentration of the doping concentration profile of the body region. For example, dopants of the body strengthening region may be implanted with a higher dose than dopants of the body region.

For example, a doping concentration of the body structure at the first vertical reference level at or close to the electrode trench structure may be predominantly determined by the doping concentration of the body region. This allows for adjusting the channel behavior, e.g. threshold voltage, of the FET by the doping concentration profile of the body region that dominates the doping concentration of the body structure in the channel region.

For example, a doping concentration of the body structure at the first vertical reference level at or close to a bottom of the groove contact may be predominantly (e.g. by more than 50%) determined by the doping concentration of the body contact region.

For example, a doping concentration of the body structure at or close to the third vertical reference level may be predominantly determined by the doping concentration of the body strengthening region.

For example, an absolute difference between the second vertical reference level and the third vertical reference level may have a value in a range from 30% to 150%, or from 50% to 130%, of an absolute difference between the first vertical reference level and the second vertical reference level. This may allow for a beneficial breakdown behavior of the FET, for example.

For example, the electrode trench structure may include an electrode structure and a dielectric structure. The electrode structure may include a gate electrode and a field electrode. Apart from a single field electrode in the trench, also a plurality of field electrodes may be arranged in the trench, e.g. stacked over one another along the vertical direction having a part of the dielectric structure arranged between each pair of field electrodes.

The dielectric structure may include a gate dielectric part that electrically isolates the gate electrode from a surrounding part of the semiconductor substrate, for example. For example, the gate dielectric may be an insulating material such as an oxide, e.g., SiO₂, a nitride, e.g., Si₃N₄, a high-k dielectric, or a low-k dielectric, or any combination thereof. The dielectric structure may further include a field dielectric that electrically isolates the field electrode(s) from a surrounding part of the semiconductor substrate, for example. For example, the field dielectric may be an insulating material such as an oxide, e.g., SiO₂, a nitride, e.g., Si₃N₄, a high-k dielectric, or a low-k dielectric, or any combination thereof. For example, the field dielectric may be formed as or include a thermal oxide and/or a deposited and annealed oxide. The field dielectric may have a larger thickness than the gate dielectric, for example. The gate electrode and field electrode(s) may be formed of one or more conductive materials, e.g. metal, metal silicide, metal compound, highly doped semiconductor material such as highly doped polycrystalline silicon. For example, the gate electrode may be a single layer, e.g. a highly doped polycrystalline layer, or a stack of layers.

For example, a part of the dielectric structure may be arranged between the gate electrode and the field electrode. In case of an n-channel FET, this may allow for improving the electric field characteristic for keeping holes generated during an avalanche breakdown event away from the channel region at the gate electrode, for example.

For example, the maximum vertical distance may be larger than a vertical distance from a bottom of the gate electrode to the top surface of the mesa. In case of an n-channel FET, holes generated during an avalanche breakdown event may be kept away from the channel region/gate electrode/gate dielectric, for example.

For example, the maximum vertical distance may be smaller than a vertical distance from a top of the field electrode to the top surface of the mesa.

For example, the FET may be a vertical FET having a source electrode over a first surface of the semiconductor substrate. The vertical FET may further have a drain electrode over a second surface of the semiconductor substrate, the second surface being opposite to the first surface.

Details with respect to structure or function or technical benefit of features described above with respect to a FET likewise apply to the exemplary methods described herein.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded. Processing a semiconductor substrate wafer for manufacturing the FET may comprise one or more optional additional features corresponding to one or more aspects mentioned in connection with the proposed concept or one or more examples described above or below.

An example of the present disclosure relates to a method of manufacturing a field effect transistor, FET. The method includes forming a mesa arranged in a semiconductor substrate between an electrode trench structure along a first lateral direction. The method further includes forming a groove contact extending into the mesa from a top surface of the mesa. A bottom of the groove contact is located a first vertical reference level. The method further includes forming a source region of a first conductivity type in the mesa. The method further includes forming a body structure of a second conductivity type in the mesa. The method further includes forming a drift region of the first conductivity type in the mesa. The drift region forms a pn junction with the body structure. The pn junction has a minimum vertical distance to the top surface of the mesa at a second vertical reference level and a maximum vertical distance to the top surface of the mesa at a third vertical reference level. At a fourth vertical reference level, a doping concentration of the body structure may increase by a factor of 5 to 100 along the first lateral direction from the electrode trench structure towards a center of the mesa. The fourth vertical reference level is located between the second vertical reference level and the first vertical reference level at a first vertical distance to the first reference level. The first vertical distance may be by a factor of 1.5 to 10 larger than a second vertical distance from the fourth vertical reference level to the second vertical reference level.

For example, forming the body structure may include forming a superposition of doping concentration profiles of at least a body region, a body contact region, and a body strengthening region. The pn junction at the third vertical reference level may coincide with an intersection, along the vertical direction, between a doping concentration profile of the body strengthening region and a doping concentration profile of the drift region. For example, the doping concentration profile of the body strengthening region may extend deeper into the mesa region from the top surface than the doping concentration profile of the body region. The doping concentration profile of the body region may extend deeper into the mesa region from the top surface than the doping concentration profile of the body contact region.

For example, the body region may be formed, e.g. by ion implantation of dopants, before forming the forming the groove contact.

For example, forming the groove contact may include forming a groove, e.g. by an etch process using an etch mask. Thereafter, forming the body contact region may include introducing dopants into the semiconductor substrate through a bottom of the groove by a first ion implantation process. Forming the body strengthening region may include introducing dopants into the semiconductor substrate through a bottom of the groove by a second ion implantation process. The second ion implantation process may be carried out after or before the first ion implantation process. Electrical activation of the dopants of the body contact region and the dopants of the body strengthening region may be carried out by a common thermal annealing process. In other words, the implanted dopants may be activated with one and the same thermal budget.

For example, an ion implantation energy of the first ion implantation process may be smaller than an ion implantation energy of the second ion implantation process. For example, the ion implantation energy of the first ion implantation process may range from 3% to 25% of an ion implantation energy of the second ion implantation process when using same dopant species, e.g. BF₂.

The method of any of the three preceding claims, wherein an ion implantation dose of the first ion implantation process may be larger than an ion implantation dose of the second ion implantation process.

The examples and features described above and below may be combined.

In the following, further examples of field effect transistors, FETs, are explained in connection with the accompanying drawings. Functional and structural details described with respect to the examples above shall likewise apply to the exemplary embodiments illustrated in the figures and described further below. In the illustrated examples, the first conductivity is n-type and the second conductivity type is p-type for an n-channel FET. However, the first conductivity type may also be p-type and the second conductivity type may be n-type for a p-channel FET.

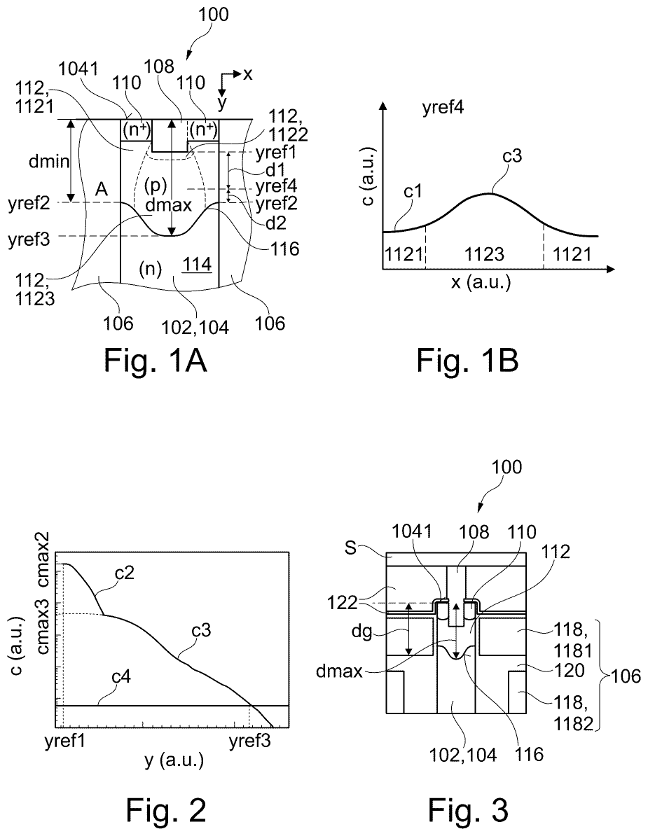

FIG. 1A schematically and exemplarily shows a cross-sectional view of a part of a transistor cell of a FET 100.

The FET 100 includes a semiconductor substrate 102. For example, the semiconductor substrate 102 may include a base substrate and an n-doped semiconductor layer on the base substrate, e.g. an epitaxial layer formed by a layer deposition process.

The semiconductor substrate 102 has a mesa 104 that is arranged between an electrode trench structure 106 along a first lateral direction x. The mesa 104 may be defined when forming trenches of the electrode trench structure 106 by a masked etch process, for example.

Electric contact to the semiconductor substrate 102 is provided by a groove contact 108 extending into the mesa 104 from a top surface 1041 of the mesa 104. At a first vertical reference level yref1, a bottom of the groove contact 108 is positioned.

An n⁺-doped source region 110 is formed in the mesa 104. The n⁺-doped source region 110 laterally adjoins to the electrode trench structure 106 on one side and further adjoins to the groove contact 108 on the other side.

A p-doped body structure 112 is formed below the source region 110. The p-doped body structure 112 is based on a superposition of p-type doping concentration profiles, e.g. a superposition of a doping concentration profile defining a body region 1121, a doping concentration profile defining a body contact region 1122, and a doping concentration profile defining a body strengthening region 1123.

An n-doped drift region 114 forms a pn junction 116 with the body structure 112 in the mesa 104. The pn junction 116 has a minimum vertical distance dmin to the top surface 1041 of the mesa 104 at a second vertical reference level yref2. The minimum vertical distance dmin of the pn junction 116 is located at or close to a sidewall of the electrode trench structure 106. The pn junction 116 further has a maximum vertical distance dmax to the top surface 1041 of the mesa 104 at a third vertical reference level yref3. The maximum vertical distance dmax of the pn junction 116 is located at or close to a center of the mesa 104 along the first lateral direction x.

Referring to FIG. 1A and the schematic graph of FIG. 1B, an exemplary doping concentration c of the body structure 112 along the first lateral direction x is illustrated with respect to a fourth vertical reference level yref4. The first vertical distance d1 is by a factor of 1.5 to 10 larger than a second vertical distance d2 from the fourth vertical reference level yref4 to the second vertical reference level yref2. At the fourth vertical reference level yref4, the doping concentration c of the body structure 112 increases by a factor of 5 to 100 along the first lateral direction x from the electrode trench structure 106 towards a center of the mesa 104. As is illustrated in a simplified manner in FIG. 1B, the doping concentration c of the body structure 112 at the second vertical reference level yref2 at or close to the electrode trench structure 106 is predominantly determined by a doping concentration c1 of the body region 1121, and the doping concentration c of the body structure 112 at or close to the third vertical reference level yref3 is predominantly determined by a doping concentration c3 of the body strengthening region 1123. Referring to FIG. 1A, an absolute difference between the second vertical reference level yref2 and the third vertical reference level yref3 may have a value in a range from 30% to 150% of an absolute difference between the first vertical reference level yref1 and the second vertical reference level yref2.

Referring to FIG. 1A and the schematic graph of FIG. 2, an exemplary doping concentration c of the body structure 112 is illustrated along the vertical direction y with respect to a center of the mesa 102. The pn junction 116 at the third vertical reference level yref3 is located at or close to an intersection, along the vertical direction y, between a doping concentration profile c3 of the body strengthening region 1123 and a doping concentration profile c4 of the drift region 114. The doping concentration c of the body structure 112 at the first vertical reference level yref1 at or close to a bottom of the groove contact 108 is predominantly determined by the doping concentration c2 of the body contact region 1122.

A maximum concentration cmax2 of the doping concentration profile c2 of the body contact region 1122 may be larger by a factor of 5 to 200 than a maximum concentration cmax3 of the doping concentration profile c3 of the body strengthening region 1123.

Sub-regions of the body structure 112 are named similar to the doping concentration profile, e.g. “body region” for the “body concentration profile”, in those parts of the body structure 112 where a value of the respective doping concentration profile is larger than a value of each of the other doping concentration profiles of the body structure 112. The doping concentration profile is determined by the manufacturing process, e.g. ion implantation energy, dose and dopant species. For example, a sub-region of the body structure 112 may be named body contact region 1122 although dopants of the doping concentration profile c3 of the body strengthening region 1123 or dopants of doping concentration profile c1 of the body region 1121 are also present in the body contact region 1122. However, in the body contact region 1122 a concentration of dopants of the doping concentration profile c2 (body contact region) is larger than a concentration of dopants of the doping concentration profile c1 (body region) or c3 (body strengthening region).

Referring to FIG. 2, a maximum concentration cmax2 of the doping concentration profile c2 of the body contact region 1122 may be larger by a factor of 5 to 200 than a maximum concentration cmax3 of the doping concentration profile c3 of the body strengthening region 1123.

FIG. 3 schematically and exemplarily shows a cross-sectional view of a part of a transistor cell of another configuration example of a FET 100.

The electrode trench structure 106 of the FET 100 includes an electrode structure 118 and a dielectric structure 120. The electrode structure 118 includes a gate electrode 1181 and a field electrode 1182. A part of the dielectric structure 120 is arranged between the gate electrode 1181 and the field electrode 1182.

The FET 100 further includes a source electrode S over the top surface 1041 of the mesa 104 and over the electrode trench structure 106. The source electrode S is electrically isolated from the gate electrode 1181 by an intermediate dielectric 122 that is arranged between the gate electrode 1181 and the source electrode S.

In the configuration example illustrated in FIG. 3, the maximum vertical distance dmax is larger than a vertical distance dg from a bottom of the gate electrode 1181 to the top surface 1041 of the mesa 104. Moreover, the maximum vertical distance dmax is smaller than a vertical distance df from a top of the field electrode 1182 to the top surface 1041 of the mesa 104. In some other configuration examples, the maximum vertical distance dmax may also be equal to or larger than the vertical distance df from a top of the field electrode 1182 to the top surface 1041 of the mesa 104.

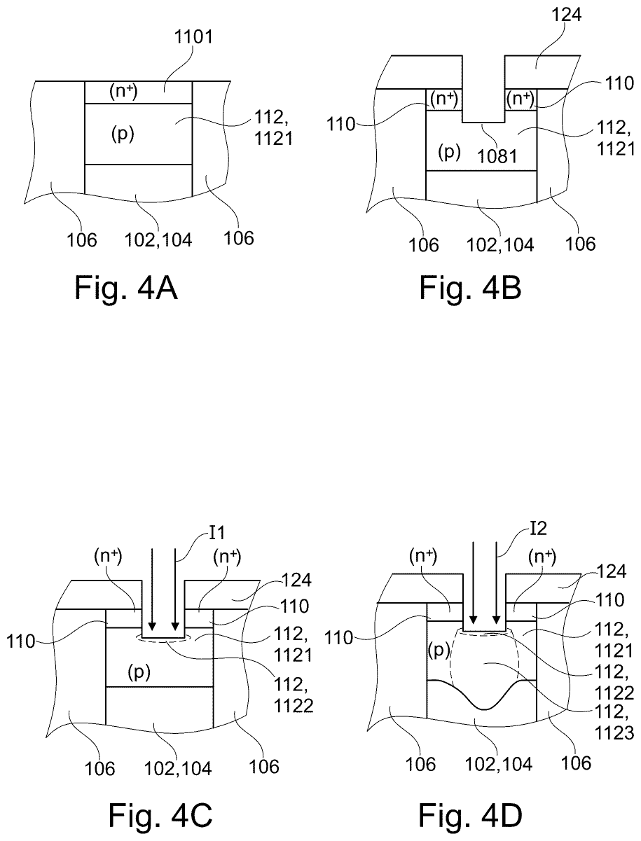

The schematic cross-sectional views of FIGS. 4A to 4D illustrate process features of manufacturing FETs 100 as described herein.

Referring to FIG. 4A, the body region 1121 of the body structure 112 and a source layer 1101 are formed before forming a groove contact, e.g. by ion implantation of dopants.

Referring to FIG. 4B, a groove 1081 of the groove contact is formed by an etch process using a mask 124 after forming the body region 1121 and after forming the source layer 1101. The etch process pattern the source layer 1101 into the source regions 110.

Referring to FIG. 4C, after forming the groove 1081, dopants are introduced into the semiconductor substrate 102 through a bottom of the groove 1081 by a first ion implantation process 11 for forming the body contact region 1122.

Referring to FIG. 4D, further dopants are introduced into the semiconductor substrate 102 through a bottom of the groove 1081 by a second ion implantation process I2 for forming the body strengthening region 1123. The process illustrated in FIG. 4C may also be carried out after the process illustrated in FIG. 4D. An ion implantation energy of the first ion implantation process I1 may be smaller than an ion implantation energy of the second ion implantation process I2, e.g. for a common dopant type such as, for example, boron. An ion implantation dose of the first ion implantation process may be larger than an ion implantation dose of the second ion implantation process, e.g. for a common dopant type such as, for example, boron.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A field effect transistor (FET), comprising:
a semiconductor substrate having a mesa arranged between an electrode trench structure along a first lateral direction;
a groove contact extending into the mesa from a top surface of the mesa, wherein a bottom of the groove contact is located at a first vertical reference level and the mesa includes:
a source region of a first conductivity type;
a body structure of a second conductivity type; and
a drift region of the first conductivity type forming a pn junction with the body structure,
wherein the pn junction has a minimum vertical distance to the top surface of the mesa at a second vertical reference level and a maximum vertical distance to the top surface of the mesa at a third vertical reference level,
wherein at a fourth vertical reference level, a doping concentration of the body structure increases by a factor of 5 to 100 along the first lateral direction from the electrode trench structure towards a center of the mesa, the fourth vertical reference level being located between the second vertical reference level and the first vertical reference level at a first vertical distance to the first reference level,
wherein the first vertical distance is by a factor of 1.5 to 10 larger than a second vertical distance from the fourth vertical reference level to the second vertical reference level.

2. The FET of claim 1, wherein the body structure includes a superposition of doping concentration profiles of at least a body region, a body contact region, and a body strengthening region, and wherein the pn junction at the third vertical reference level coincides with an intersection, along the vertical direction, between a doping concentration profile of the body strengthening region and a doping concentration profile of the drift region.

3. The FET of claim 2, wherein a maximum concentration of the doping concentration profile of the body contact region is larger by a factor of 5 to 200 than a maximum concentration of the doping concentration profile of the body strengthening region.

4. The FET of claim 2, wherein a maximum concentration of the doping concentration profile of the body strengthening region is larger by a factor of 5 to 200 than a maximum concentration of the doping concentration profile of the body region.

5. The FET of claim 2, wherein a doping concentration of the body structure at the second vertical reference level at or close to the electrode trench structure is predominantly determined by the doping concentration of the body region.

6. The FET of claim 2, wherein a doping concentration of the body structure at the first vertical reference level at or close to a bottom of the groove contact is predominantly determined by the doping concentration of the body contact region.

7. The FET of claim 2, wherein a doping concentration of the body structure at or close to the third vertical reference level is predominantly determined by the doping concentration of the body strengthening region.

8. The FET of claim 1, wherein an absolute difference between the second vertical reference level and the third vertical reference level has a value in a range from 30% to 150% of an absolute difference between the first vertical reference level and the second vertical reference level.

9. The FET of claim 1, wherein the electrode trench structure includes an electrode structure and a dielectric structure, the electrode structure including a gate electrode and a field electrode.

10. The FET of claim 9, wherein a part of the dielectric structure is arranged between the gate electrode and the field electrode.

11. The FET of claim 10, wherein the maximum vertical distance is larger than a vertical distance from a bottom of the gate electrode to the top surface of the mesa.

12. The FET of claim 11, wherein the maximum vertical distance is smaller than a vertical distance from a top of the field electrode to the top surface of the mesa.

13. The FET of claim 1, wherein the FET is a vertical FET having a source electrode over a first surface of the semiconductor substrate and a drain electrode over a second surface of the semiconductor substrate, the second surface being opposite to the first surface.

14. A method of manufacturing a field effect transistor (FET), the method comprising:
forming a mesa arranged in a semiconductor substrate between an electrode trench structure along a first lateral direction;
forming a groove contact extending into the mesa from a top surface of the mesa, wherein a bottom of the groove contact is located a first vertical reference level;
forming a source region of a first conductivity type in the mesa;
forming a body structure of a second conductivity type in the mesa;
forming a drift region of the first conductivity type in the mesa, the drift region forming a pn junction with the body structure, the pn junction having a minimum vertical distance to the top surface of the mesa at a second vertical reference level and a maximum vertical distance to the top surface of the mesa at a third vertical reference level,
wherein at a fourth vertical reference level, a doping concentration of the body structure increases by a factor of 5 to 100 along the first lateral direction from the electrode trench structure towards a center of the mesa, the fourth vertical reference level being located between the second vertical reference level and the first vertical reference level at a first vertical distance to the first reference level,
wherein the first vertical distance is by a factor of 1.5 to 10 larger than a second vertical distance from the fourth vertical reference level to the second vertical reference level.

15. The method of claim 14, wherein forming the body structure comprises forming a superposition of doping concentration profiles of at least a body region, a body contact region, and a body strengthening region, and wherein the pn junction at the third vertical reference level coincides with an intersection, along the vertical direction, between a doping concentration profile of the body strengthening region and a doping concentration profile of the drift region.

16. The method of claim 15, wherein the body region is formed before forming the forming the groove contact.

17. The method of claim 15, wherein:
forming the groove contact comprises forming a groove and thereafter forming the body contact region comprises introducing dopants into the semiconductor substrate through a bottom of the groove by a first ion implantation process; and
forming the body strengthening region comprises introducing dopants into the semiconductor substrate through a bottom of the groove by a second ion implantation process.

18. The method of claim 17, wherein an ion implantation energy of the first ion implantation process is smaller than an ion implantation energy of the second ion implantation process.

19. The method of claim 17, wherein an ion implantation dose of the first ion implantation process is larger than an ion implantation dose of the second ion implantation process.
